(19) United States
(12) Patent Application Publication
(10) Pub. No.: US 2009/0215224 A1
(43) Pub. Date: Aug. 27, 2009

(54) COATING METHODS AND APPARATUS FOR MAKING A CIGS SOLAR CELL

(75) Inventors: Wei-Zhong Li, San Jose, CA (US); Ken Tang, Higashigurume-shi (JP)

Correspondence Address: KASHA LAW LLC, 10310 POTOMAC CORNER DRIVE, ROCKVILLE, MD, 20850, US

(73) Assignee: Film Solar Tech Inc.

(21) Appl. No.: 12/034,715

(22) Filed: Feb. 21, 2008

(51) Int. Cl. H01L 21/06; C23C 16/00; C23C 14/34

(52) U.S. Cl. 438/102; 118/719; 204/298.02; 257/E21.068

(57) ABSTRACT

A method for manufacturing a thin film solar cell involves applying an inductively-coupled-plasma during the deposition of selenium. A precursor thin film is formed. The precursor thin film can include copper, indium, and gallium. The inductively-coupled-plasma is applied to the selenium as the selenium is deposited into the precursor thin film to produce the thin film. The selenium is deposited into precursor thin film by evaporation, sputtering, or using a reactive gas. An inert gas is used as a carry and discharge gas. The precursor thin film and the selenium are deposited using a deposition system. The deposition system includes an inductively-coupled-plasma device. The inductively-coupled-plasma device includes a quartz plate, a plasma discharge coil, and an inlet system. The deposition can be an in-line system, a roll-to-roll system, or a hybrid system.

### BACKGROUND OF THE INVENTION

1. Field of the Invention

Embodiments of the present invention relate to coating methods and coating apparatus for producing copper, indium, gallium, and selenium (Cu(In₁₋ₓGaₓ)(Se)₂, i.e. “CIGS”) thin film for solar cell applications. More particularly, embodiments of the present invention relate to methods for introducing an inductively-coupled-plasma (ICP) in an inline or roll-to-roll type coating apparatus to improve a chemical reaction under low temperature for making high quality CIGS crystals.

2. Background Information

Copper, indium, gallium, and selenium (Cu(In₁₋ₓGaₓ)(Se)₂, i.e. “CIGS”) thin film solar cells offer many advantages over the silicon based solar cells, including, but not limited to, lower cost, shorter manufacturing cycle, higher reliability, better performance under low light conditions, and better performance for the light incidence at a lower angle of incidence. Conventional CIGS coating methods and apparatus use multiple sources to co-evaporate and/or sputter the precursor, or copper, indium, and gallium (CIG), and then add selenium to CIG using hydrogen selenide (H₂Se) gas to form a CIGS film under high temperature in a different chamber. This approach has many disadvantages, including, but not limited to, long process times, high cost, and the requirement that the process be performed under high temperature conditions.

In view of the foregoing, it can be appreciated that a substantial need exists for systems and methods that can advantageously produce CIGS with higher efficiency, with lower cost, and without the requirement that the process be performed under high temperature conditions.

### BRIEF DESCRIPTION OF THE DRAWINGS

FIG. 1 is a cross-sectional view of an exemplary module type copper, indium, gallium, and selenium (Cu(In₁₋ₓGaₓ)(Se)₂, i.e. “CIGS”) solar cell, in accordance with an embodiment of the present invention.

FIG. 2 is a cross-sectional view of an exemplary grid type CIGS solar cell, in accordance with an embodiment of the present invention.

FIG. 3 is a flowchart showing a method for manufacturing a thin film including selenium, in accordance with an embodiment of the present invention.

FIG. 4 is a schematic diagram of an apparatus for manufacturing a thin film including selenium, in accordance with an embodiment of the present invention.

FIG. 5 is a flowchart showing a method for manufacturing a thin film, in accordance with an embodiment of the present invention.

FIG. 6 is a schematic diagram of an exemplary in-line hybrid deposition system having inductively-coupled-plasma (ICP) reaction zones and separate sputtering and/or evaporation sources, in accordance with an embodiment of the present invention.

FIG. 7 is a schematic diagram of an exemplary in-line hybrid deposition system for three-stage deposition, in accordance with an embodiment of the present invention.

FIG. 8 is a schematic diagram of an exemplary roll-to-roll hybrid deposition system having ICP reaction zones and separate sputtering and/or evaporation sources, in accordance with an embodiment of the present invention.

Before one or more embodiments of the invention are described in detail, one skilled in the art will appreciate that the invention is not limited in its application to the details of construction, the arrangements of components, and the arrangement of steps set forth in the following detailed description or illustrated in the drawings. The invention is capable of other embodiments and of being practiced or being carried out in various ways. Also, it is to be understood that the phraseology and terminology used herein is for the purpose of description and should not be regarded as limiting.

### DETAILED DESCRIPTION OF THE INVENTION METHODS AND APPARATUS

FIG. 1 is a cross-sectional view of a module type copper, indium, gallium, and selenium (Cu(In₁₋ₓGaₓ)(Se)₂, i.e. “CIGS”) solar cell 10, in accordance with an embodiment of the present invention. Solar cell 10 is formed, for example, on sodium lime glass substrate 17. Molybdenum layer 16 is first deposited on the substrate 17 as an electrode and is then scribed into several cells. CIGS layer 15, a buffer layer 13, and an i-electrode layer 12 are deposited on molybdenum layer 16, and, again, these layers are scribed into the required pattern. Finally, transparent conductor layer 14 is deposited and scribed as another electrode for each cell.

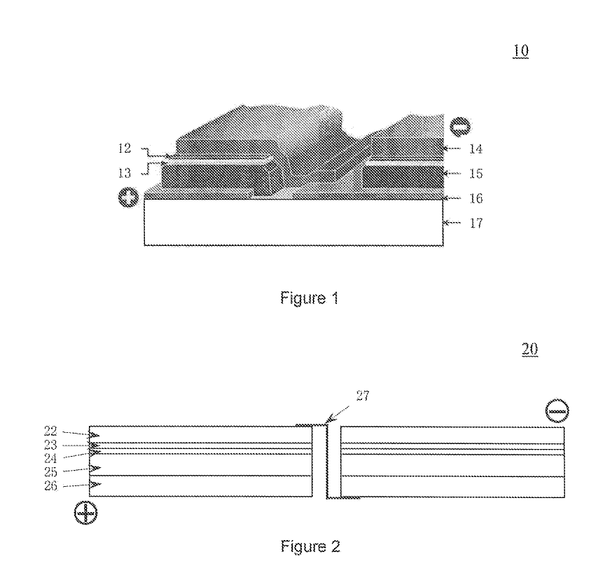

FIG. 2 is a cross-sectional view of a grid type CIGS solar cell 20, in accordance with an embodiment of the present invention. A grid type CIGS solar cell is usually formed on flexible substrate. A flexible substrate can include, but is not limited to, molybdenum foil, stainless foil, or plastic sheet. CIGS solar cell 20 is formed on metal foil substrate 26, for example. Since substrate 26 is a metal, CIGS layer 25 can be directly deposited on substrate 26, which is followed by the deposition of buffer layer 24 and i-electrode layer 23. Finally, transparent conductor layer 22 is deposited as an electrode. In a roll-to-roll deposition process, CIGS solar cell 20 is cut into pieces with the required area. The transparent conductor layer 22 of one cell is connected by electric wires 27 to a substrate (i.e. another electrode) of another cell.

One embodiment of the present invention is a method for introducing an inductively-coupled-plasma (ICP) during the deposition of selenium to copper, indium, and gallium (CIG) to improve CIGS thin film quality and manufacturing efficiency and to allow deposition at a lower process temperature. A CIGS thin film can be manufactured using an in-line or roll-to-roll apparatus, for example. An in-line and roll-to-roll apparatus includes, for example, linear or planar magnetron sputtering sources, linear thermal evaporation sources, and reactive ICP sources.

In another embodiment of the present invention, an ICP is applied to a selenium evaporation zone during the deposition to stimulate the selenium molecule atoms to their excited states and to separate the cluster selenium (e.g. (Se₂)ₙ) molecule into a single Se₂ molecule or Se atom in order to improve CIGS thin film quality and manufacturing efficiency. The ICP enables the excited selenium molecules and atoms to have a higher affinity to react with the precursor CIG that is deposited at the prior stage.

To introduce ICP into the reaction, an ICP device can be installed in a coating chamber. An ICP device can include, but is not limited to, a quartz chamber, plasma discharge coils, and an inlet system. A plasma discharge coil can be placed either inside or outside of a vacuum chamber. A quartz plate is used to separate the vacuum chamber and the coil. The coil is used to generate a middle frequency wave for discharging the plasma.

In another embodiment of the present invention, introducing ICP into the reaction can be used to excite not only selenium, but also other materials including, but not limited to, sulfur and tellurium. Further, the introduction of ICP can be used to inlet the gases including, but not limited to, hydrogen selenide (H₂Se), hydrogen sulfide (H₂S), di-ethylselenide DESe to make copper, indium, gallium, and selenium (CuInGaSe₂) or copper, indium, gallium, selenium, and sulfur (CuInGaSeS). Also, applying an ICP can improve the deposition rate and quality for some oxidant layers including, but not limited to, the buffer layers zinc magnesium oxide (ZnMgO), any zinc oxide (i-ZnO), zinc oxide (ZnO) doped aluminum, ZnO doped gallium, and the transparent conduct layer ZnO doped boron.

During the formation of a thin film containing metal oxide coatings, substrates are mounted on a rotating cylindrical drum carrier on a continuous moving web in an in-line translational processing configuration, or in a roll-to-roll processing configuration. The substrates are moved through a set of processing stations including: (1) at least one preferably evaporation device, e.g., a planar magnetron, a dual rotating magnetron, or a linear thermal resistance evaporation source, operates in a metal deposition mode for depositing copper, indium, gallium, zinc, or other alloy metals including, but not limited to, CIG, InGa, ZnMg, ZnAl, zinc and gallium (ZnGa), zinc and boron (ZnB); and (2) a planar ICP device or plasma source operates in a reactive plasma mode to produce an uniform and high intensity radical flux using oxygen for oxidation, or H₂Se, hydrogen sulfide (H₂S), DESe gas for selenization with argon, or another inert gas as a carrier.

The evaporation and ICP sources can be located at the top of the chamber, at the base of the chamber, or on the sides of the chamber. Also, the arrangement is scalable in that a plurality of evaporation and ICP sources can be used in each processing station to increase the deposition rates and the number of materials formed. Various processing stations can be arranged in a chamber for depositing, selenizing, and/or oxidizing different metals and alloys separately in sequence. For example, in the selenizing process, the sequence can be: indium and gallium (InGa) deposition, selenization, copper (Cu) deposition, selenization, InGa deposition, selenization and/or sulphurizing. In the oxidizing process, the sequence can be: zinc and magnesium (ZnMg) deposition, oxidizing, zinc (Zn) depositing, oxidizing, zinc and aluminum (ZnAl) deposition, and oxidizing.

An in-line or a roll-to-roll system combined with linear or planar magnetron sputtering sources, linear thermal evaporation sources, and reactive ICP sources provide fast, high quality, and uniform deposition on a large area of both flat and flexible substrates. The high deposition rate under low process temperature allows deposition of CIGS coatings on low melting temperature substrates, such as plastics.

To prevent the diffusion of selenium molecules during the process, selenium molecular diffusion lock systems are introduced into a coating chamber. A diffusion lock system includes a cooling baffle to catch selenium molecules at a low temperature to prevent the selenium molecules from diffusing to other chambers.

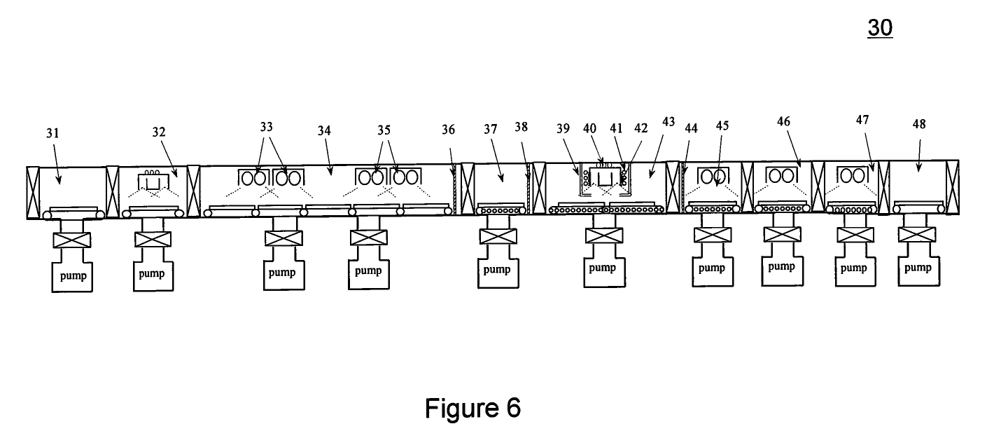

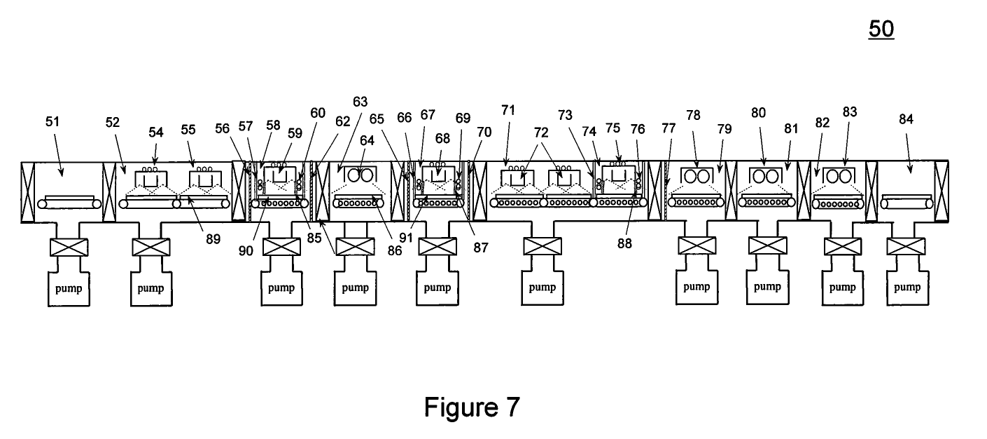

To optimize the coating process, a hybrid deposition process can be used to either evaporate or sputter the copper, indium, gallium, and selenium by thermal evaporation sources and/or sputtering sources. A hybrid deposition system is a system in which both evaporation and sputtering methods are used. Selenization processes can be accomplished by either a hybrid system with ICP as shown in FIG. 6 or a 3-stage hybrid deposition system shown in FIG. 7.

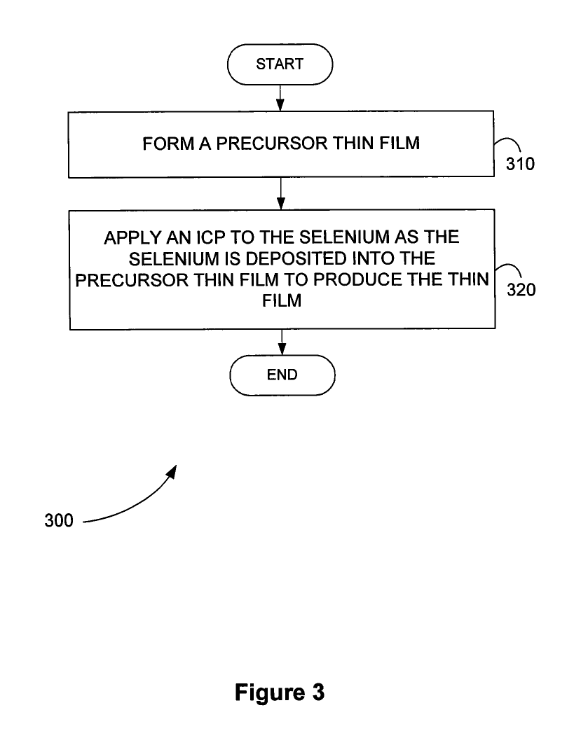

FIG. 3 is a flowchart showing a method 300 for manufacturing a thin film including selenium, in accordance with an embodiment of the present invention.

In step 310 of method 300, a precursor thin film is formed. The precursor thin film includes InGa, for example. In another embodiment of the present invention, the precursor thin film includes CIG.

In step 320, an ICP is applied to the selenium as the selenium is deposited into the precursor thin film to produce the thin film. The selenium is deposited into precursor thin film by evaporation, for example. In another embodiment of the present invention, the selenium is deposited into the precursor thin film by sputtering. In another embodiment of the present invention, the selenium is deposited into the precursor thin film using a reactive gas. The reactive gas includes H₂Se, for example. In another embodiment of the present invention, the reactive gas includes DESe. An inert gas is used as a carry and discharge gas. The inert gas includes comprises argon, for example.

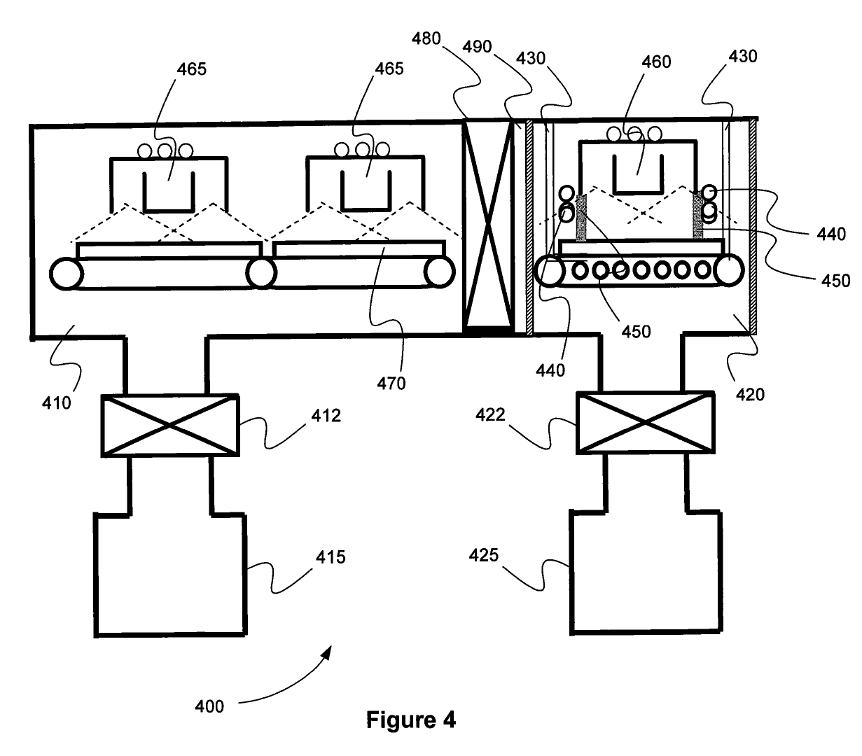

FIG. 4 is a schematic diagram of an apparatus 400 for manufacturing a thin film including selenium, in accordance with an embodiment of the present invention. Apparatus 400 includes first deposition chamber 410 and second deposition chamber 420. First deposition chamber 410 and second deposition chamber 420 are, for example, vacuum chambers. First deposition chamber 410 is evacuated using valve 412 and pump 415, for example. Second deposition chamber 420 is evacuated using valve 422 and pump 425, for example.

Substrate 470 moves from first deposition chamber 410 to second deposition chamber 420 through valve 480 in apparatus 400, for example. Apparatus 400 can be part of a hybrid in-line deposition system, for example. In another embodiment of the present invention, apparatus 400 can be part of a roll-to-roll deposition system.

First deposition chamber 410 is used to form a precursor thin film. Second deposition chamber 420 includes an inductively-coupled plasma device that applies an inductively-coupled plasma to the selenium as the selenium is deposited into the precursor thin film. The inductively-coupled plasma device can include quartz plates 430, plasma discharge coils 440, and inlet systems 450.

Quartz plates 430 are shown placed between plasma discharge coils 440 and second deposition chamber 420, for example. In another embodiment of the present invention, plasma discharge coils 440 are placed inside second deposition chamber 420. In another embodiment of the present invention, plasma discharge coils 440 are placed outside of second deposition chamber 420.

Second deposition chamber 420 includes evaporation source 460, for example. In another embodiment of the present invention second deposition chamber 420 includes a sputtering source. First deposition chamber 410 includes evaporation sources 465, for example.

Apparatus 400 can include selenium molecular diffusion lock 490 located between first deposition chamber 410 and second deposition chamber 420.

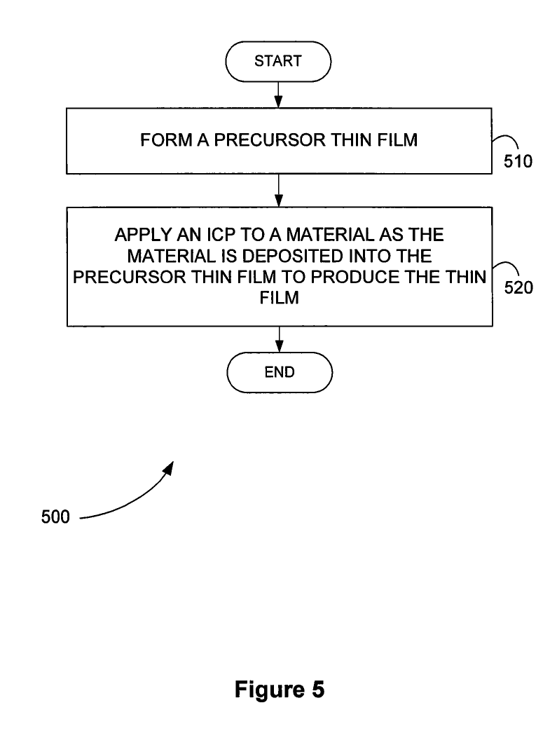

FIG. 5 is a flowchart showing a method 500 for manufacturing a thin film, in accordance with an embodiment of the present invention.

In step 510 of method 500, a precursor thin film is formed.

In step 520, an ICP is applied to a material as the material is deposited into the precursor thin film to produce the thin film. The material can include, but is limited to, tellurium, sulfur, or oxygen.

### EXAMPLES

FIG. 6 is a schematic diagram of an exemplary in-line hybrid deposition system 30 having ICP reaction zones and separate sputtering and/or evaporation sources, in accordance with an embodiment of the present invention. Deposition system 30 can be used to manufacture a CIGS solar cell. A substrate is loaded and preheated in vacuum chamber 31. A Molybdenum layer is deposited on the substrate in chamber 32. A precursor CIG layer is deposited in chamber 34. The substrate is then heated again to the required temperature, for example 350 degrees Celsius, in chamber 37. Selenium is added to the CIG layer in chamber 43. After the selenization process, chambers 45, 46, and 47 are used to deposit a buffer layer, an i-ZnO, and a transparent conductor layer respectively. Finally, the finished CIGS thin film is cooled down in the chamber 48.

An ICP device in chamber 43 includes quartz chamber 39, plasma discharge coils 41, and inlet system 42. Deposition system 30 includes diffusion lock systems 36, 38 and 44. Sputtering sources 33 and 35 are used in chamber 34. Thermal evaporation source 40 is used selenization in chamber 43.

FIG. 7 is a schematic diagram of an exemplary in-line hybrid deposition system 50 for three-stage deposition, in accordance with an embodiment of the present invention. In system 50, a substrate preloaded and preheated in chamber 51. InGa is deposited coating chambers 52 and 71. Selenium is deposited in chambers 58, 67, and 74. Cu is deposited in chamber 63. A buffer layer is deposited in chamber 79. A ZnO layer or i-electrode is deposited in chamber 8. A conductor layer is deposited in chamber 82. Finally, the CIGS solar cell is cooled chamber 84.

Deposition system 50 employs three separate ICP devices that include quartz chambers 57, 66, and 73, plasma discharge coils 60, 69, and 76, and inlet systems 85, 87, and 88, respectively. Deposition system 50 includes diffusion lock systems 56, 62, 65, 70, and 77. Deposition system includes thermal evaporation sources 54, 55, 59, 68, 72, and 75 and sputtering sources 64, 78, 80, and 83.

In the 3-stage selenization process of system 50, InGa is coated on substrate 89 in chamber 52 at the first stage using thermal evaporation sources 54 and 55. Substrate 90 goes through a first selenization process in chamber 58 where the temperature of substrate 90 is rapidly raised to, for example, 350 degrees Celsius.

At the second stage, copper (Cu) is deposited on substrate 86 by sputtering source 64. Selenium is deposited again on substrate 91 in chamber 67 using thermal evaporation system 68. In chamber 67, the temperature of substrate 91 is raised again, for example, from 350 degrees Celsius to 550 degrees Celsius.

In the third stage, InGa is deposited again in chamber 71. The InGa coating process in chamber 71 is similar to the process in the first stage except that it is done at a higher temperature. Selenium is deposited for a third time in chamber 74.

During selenization, if the selenium is deposited by a thermal or sputtering process, argon or an inert gas can be used as a discharge gas. If the reactive gases are others such as H₂Se or DESe, then argon or other inert gas can also be used as the discharge gas. Chambers 79, 81, and 82 are used to deposit a buffer layer, an i-electrode layer and a transparent conductor layer, respectively.

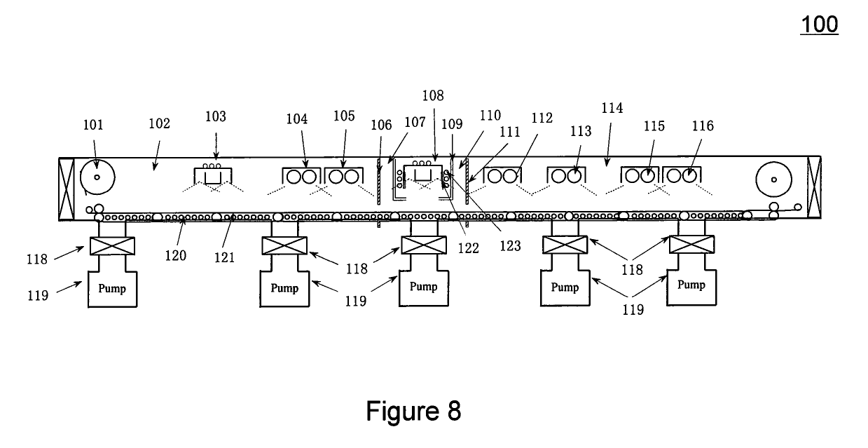

FIG. 8 is a schematic diagram of an exemplary roll-to-roll hybrid deposition system 100 having ICP reaction zones and separate sputtering and/or evaporation sources, in accordance with an embodiment of the present invention. In deposition system 100, chamber 102 is a deposition area. In chamber 102, sodium fluoride (NaF) is deposited using evaporation source 103 and precursor CIG is deposited using sputtering sources 104 and 105. Selenium is deposited in chamber 107. A buffer layer, ZnO layer and conductor layer are deposited in chamber 114.

Selenization chamber 107 includes an ICP device. The ICP device includes quartz chamber 109, plasma discharge coils 123, and inlet system 122. Deposition system 100 includes diffusion lock systems 106 and 111. Deposition system 100 also includes sputtering sources 104, 105, 112, 113 115, and 116 and thermal evaporation sources 103 and 108.

System 100 is an embodiment of a roll-to-roll hybrid system 100, where a roller 101 and a translational system 120 are specifically designed for coating flexible substrate 121. Flexible substrate 121 is, for example, a metal foil.

When forming CIGS on flexible substrate 121, the CIGS deposition and selenium reactive processes are both done in chamber 102. A very thin layer of sodium compound can be deposited on substrate 121 to promote CIGS crystallization. Selenium molecule diffusion lock system 111 is used to isolate the vacuum reactive processing area 110.

Similar to the process in the in-line system, during selenization, argon or an inert gas can be used as a carrier and a discharge gas if the selenium is deposited by a thermal or sputtering process. When other reactive gases such as H₂Se or DESe are used, argon or other inert gases may be used as the carrier and the discharge gas. A buffer layer, an i-electrode layer, and a transparent conductor layer can all be deposited in chamber 114 by magnetron sputtering systems 112, 113, 115, and 116, respectively. Each chamber of system 100 is equipped with pump and valve systems 119 and 118, respectively.

In the foregoing detailed description, systems and methods in accordance with embodiments of the present invention have been described with reference to specific exemplary embodiments. Accordingly, the present specification and figures are to be regarded as illustrative rather than restrictive. The scope of the invention is to be further understood by the numbered examples appended hereto, and by their equivalents.

Further, in describing various embodiments, the specification may have presented a method and/or process as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process should not be limited to the performance of their steps in the order written, and one skilled in the art can readily appreciate that the sequences may be varied and still remain within the spirit and scope of the various embodiments.

What is claimed is:

1. A method for manufacturing a thin film including selenium, comprising:
forming a precursor thin film; and
applying an inductively-coupled plasma to the selenium as the selenium is deposited into the precursor thin film to produce the thin film.

2. The method of claim 1, wherein the precursor thin film comprises indium and gallium (InGa).

3. The method of claim 1, wherein the precursor thin film comprises copper, indium, and gallium (CuInGa).

4. The method of claim 1, wherein the selenium is deposited into the precursor thin film by evaporation.

5. The method of claim 1, wherein the selenium is deposited into the precursor thin film by sputtering.

6. The method of claim 1, wherein the selenium is deposited into the precursor thin film using a reactive gas.

7. The method of claim 6, wherein the reactive gas comprises hydrogen selenide (H₂Se).

8. The method of claim 6, wherein the reactive gas comprises diethyl selenide (DESe).

9. The method of claim 1, wherein an inert gas is used as a carry gas and a discharge gas.

10. The method of claim 9, wherein the inert gas comprises argon.

11. An apparatus for manufacturing a thin film including selenium, comprising:
a first deposition chamber for forming a precursor thin film;
a second deposition chamber that follows the first deposition chamber in a deposition system, comprises an inductively-coupled plasma device, and applies an inductively-coupled plasma to the selenium as the selenium is deposited into the precursor thin film to produce the thin film using the inductively-coupled plasma device.

12. The apparatus of claim 11, wherein the deposition system comprises a hybrid in-line deposition system

13. The apparatus of claim 11, wherein the deposition system comprises a roll-to-roll deposition system.

14. The apparatus of claim 11, wherein the inductively-coupled plasma device comprises a quartz plate, a plasma discharge coil, and an inlet system.

15. The apparatus of claim 14, wherein the quartz plate is placed between the plasma discharge coil and the second deposition chamber.

16. The apparatus of claim 14, wherein the plasma discharge coil is placed outside of the second deposition chamber.

17. The apparatus of claim 14, wherein the plasma discharge coil is placed inside the second deposition chamber.

18. The apparatus of claim 11, wherein the second deposition chamber comprises an evaporation source.

19. The apparatus of claim 11, wherein the second deposition chamber comprises a sputtering source.

20. The apparatus of claim 11, wherein a selenium molecular diffusion lock is located between the first deposition chamber and the second deposition chamber.

21. A method for manufacturing a thin film, comprising:
forming a precursor thin film; and
applying an inductively-coupled plasma to a material as the material is deposited into the precursor thin film to produce the thin film.

22. The method of claim 21, wherein the material comprises tellurium.

23. The method of claim 21, wherein the material comprises sulfur.

24. The method of claim 21, wherein the material comprises oxygen.
